(19) United States
(12) Patent Application Publication
(10) Pub. No.: US 2025/0147423 A1
(43) Pub. Date: May 8, 2025

(54) PHOTOLITHOGRAPHIC RINSE COMPOSITIONS AND METHODS OF FORMING PATTERNS USING THE COMPOSITIONS

(71) Applicant: Samsung Electronics Co., Ltd., Suwon-si (KR)

(72) Inventors: JINJOO KIM, Suwon-si (KR); DAIKI MINAMI, Suwon-si (KR); WON-JOON SON, Suwon-si (KR); HYUNJI SONG, Suwon-si (KR); SONGSE YI, Suwon-si (KR)

(21) Appl. No.: 18/737,042

(22) Filed: Jun. 7, 2024

(30) Foreign Application Priority Data
Oct. 30, 2023 (KR) 10-2023-0146540

(51) Int. Cl. G03F 7/38

(52) U.S. Cl. CPC G03F 7/38

(57) ABSTRACT

Disclosed are photolithographic rinse compositions and methods of forming patterns using the same, the photolithographic rinse compositions including a gemini-type surfactant having a main chain including at least two hydrophobic groups and at least one hydrophilic group and at least two side chains branching from the main chain and including a hydrophilic group-including functional group, and a solvent.

### CROSS-REFERENCE TO RELATED APPLICATION

This application claims priority under 35 U.S.C. §119 to Korean Patent Application No. 10-2023-0146540 filed in the Korean Intellectual Property Office on Oct. 30, 2023, the entire contents of which are incorporated herein by reference.

### FIELD OF THE INVENTION

This disclosure relates to a photolithographic rinse composition, and a method of forming patterns using the same.

### BACKGROUND

EUV (extreme ultraviolet) lithography is considered an essential technology for manufacturing a next generation semiconductor device. EUV lithography is a pattern-forming technology using an EUV ray having a wavelength of 13.5 nm as an exposure light source. According to EUV lithography, an extremely fine pattern (e.g., less than or equal to 20 nm) may be formed in an exposure process during a manufacture of a semiconductor device.

As the pattern has a smaller size, line width roughness (LWR) of the resist pattern increases, which adversely affects device performance.

In addition, as the pattern refinement progresses, a phenomenon of the lithography process is pattern collapse after rinsing, that is, a pattern collapse problem occurs. In particular, the pattern collapse phenomenon may be more likely to occur in a pattern with a large aspect ratio.

Such a photoresist pattern collapse may be caused by a capillary force due to surface tension of a rinse composition used in the photolithography process. Accordingly, since the surface tension of the rinse composition should be lowered, there is a need to develop a composition for washing the photoresist pattern which can prevent the pattern collapse phenomenon.

Particularly, in the EUV process, since higher surface tension due to narrower spacing between the patterns acts on the photoresist pattern during the spin-drying, a per- and polyfluoroalkyl substance (PFAS)-based surfactant is used in order to improve the pattern collapse phenomenon; however, the PFAS-based surfactant needs to be replaced due to environmental hazards.

### SUMMARY OF THE INVENTION

One aspect of the present disclosure provides a photolithographic rinse composition including a per- and polyfluoroalkyl substance-free (PFAS-free) surfactant that may prevent pattern collapse.

Another aspect of the present disclosure provides a method of forming patterns using the photolithographic rinse composition.

A photolithographic rinse composition according to one aspect includes a gemini-type surfactant having a main chain including at least two hydrophobic groups, at least one hydrophilic group, at least two side chains branching from the main chain, and a hydrophilic group-containing functional group; and a solvent.

A method of forming patterns according to another aspect includes forming a photoresist film on a substrate; exposing a photoresist film; patterning the exposed photoresist film to form a photoresist pattern; and washing the photoresist pattern using the aforementioned rinse composition.

The photolithographic rinse composition according to one aspect may suppress deformation and collapse of a photoresist pattern and, thus critical dimension (CD) changes in the pattern resulting therefrom, which thereby may improve yield and productivity of the device manufacturing process.

In addition, the problem of environmental hazards of per- and polyfluoroalkyl (PFAS) surfactant can be resolved by using a per- and polyfluoroalkyl substance-free (PFAS-free) surfactant.

### BRIEF DESCRIPTION OF THE DRAWINGS

FIGS. 1 to 5 are cross-sectional views illustrating aspects of a method of forming patterns.

FIG. 6 is a schematic view illustrating an exemplary structure of a gemini-type surfactant according to an embodiment.

FIGS. 7 and 8 are schematic views illustrating degrees of distribution according to the structures of surfactants to calculate the surface distribution ratios (K).

FIG. 9 is a schematic view for illustrating a method of calculating the surface distribution ratio from the number of molecules distributed for each of the photoresist (PR) pattern-solvent interface and the solvent-air interface.

FIG. 10 shows the surface distribution ratios (K) according to Comparative Example 1 and Examples 1 to 3.

### DETAILED DESCRIPTION OF THE EMBODIMENTS

The present disclosure will be described more fully hereinafter with reference to the accompanying drawings, in which example embodiments of the invention are shown. The invention may be implemented in many different forms and is not limited to the embodiments described herein.

In order to clearly describe the present disclosure, parts which are not related to the description are omitted, and the same reference numeral refers to the same or like components, throughout the specification.

The size and thickness of each constituent element as shown in the drawings are randomly indicated for better understanding and ease of description, and this disclosure is not necessarily limited to as shown. In the drawings, the thickness of, for example, layers, films, panels, regions, and/or portions thereof, may be exaggerated for clarity and are not necessarily to scale.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion is to be disposed above or below the reference portion and does not necessarily mean “above” toward an opposite direction of gravity.

In addition, unless explicitly described to the contrary, the word “comprise,” and variations such as “comprises” or “comprising”, will be understood to imply the inclusion of stated elements but not the exclusion of any other elements.

As used herein, when a definition is not otherwise provided, “alkyl group” refers to a linear or branched aliphatic hydrocarbon group. The alkyl group may be a “saturated alkyl group” that does not contain any double or triple bonds.

Herein, the term “C2 to C12 alkyl group” means a linear or branched, substituted or unsubstituted alkyl group having 2 to 12 carbon atoms. For example, the alkyl group may include an ethyl group, an n-propyl group, an isopropyl group, an n-butyl group, an isobutyl group, a sec-butyl group, a t-butyl group, an n-pentyl group, an n-hexyl group, an n-heptyl group, an n-octyl group, an n-nonyl group, and an n-decyl group, but is not limited to the above examples.

As used herein, unless otherwise defined, “alkenyl group” refers to a linear or branched aliphatic hydrocarbon group and an aliphatic unsaturated alkenyl group containing one or more double bonds.

As used herein, unless otherwise defined, “alkynyl group” refers to a linear or branched aliphatic hydrocarbon group and an aliphatic unsaturated alkynyl group containing one or more triple bonds.

Hereinafter, a photolithographic rinse composition according to an embodiment will be described.

A photolithographic rinse composition according to an embodiment includes a gemini-type surfactant having a main chain including at least two hydrophobic groups, at least one hydrophilic group, at least two side chains branching from the main chain, and a hydrophilic group-containing functional group; and a solvent.

While a gemini-type surfactant is originally named for a surfactant consisting of two hydrophilic groups and two hydrophobic groups, as described herein, surfactants with more than two hydrophilic groups and more than two hydrophobic groups are also referred to herein as a gemini-type surfactant for convenience.

In other words, the gemini-type surfactant refers to a structure including two or more hydrophilic groups, for example, a hydrophilic group and a hydrophilic group-containing functional group, and two or more hydrophobic groups.

In more detail, the surfactant according to an embodiment of the present disclosure may be described with reference to FIG. 6.

FIG. 6 is a schematic diagram showing the structure of a gemini-type surfactant according to an embodiment of the present disclosure.

Referring to FIG. 6, the surfactant according to the present disclosure may have a structure including a main chain including at least two hydrophobic groups (B1, B2, B3) and at least one hydrophilic group (A1) and at least two side chains (A2, A3) branching from the main chain and including a hydrophilic group-containing functional group.

In the main chain of the basic structure according to FIG. 6, the main chain may be extended by adding more hydrophobic groups, a hydrophilic group may be further included between the hydrophobic groups included in the main chain, and a hydrophilic group-containing functional group branching from the extended main chain may be further included.

As an example, the surfactant may include a compound represented by Chemical Formula 1.

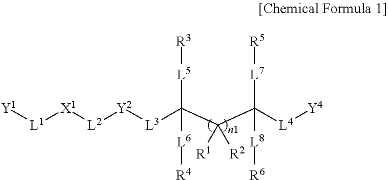

In Chemical Formula 1,
Y¹ and Y⁴ are each independently a substituted or unsubstituted C2 to C12 alkyl group that does not include fluorine; a substituted or unsubstituted C2 to C12 alkenyl group that does not include fluorine; a substituted or unsubstituted C2 to C12 alkynyl group that does not include fluorine, or any combination thereof,
Y² is a substituted or unsubstituted C1 to C10 alkylene group that does not include fluorine; a substituted or unsubstituted C2 to C10 alkenylene group that does not include fluorine; a substituted or unsubstituted C2 to C10 alkynylene group that does not include fluorine, or any combination thereof,
X¹ is a hydrophilic group,
R¹ and R² are each independently a hydrogen atom; a substituted or unsubstituted C1 to C5 alkyl group that does not include fluorine; a substituted or unsubstituted C2 to C5 alkenyl group that does not include fluorine; a substituted or unsubstituted C2 to C5 alkynyl group that does not include fluorine, or any combination thereof,
R³ to R⁶ are each independently a hydrogen atom, a substituted or unsubstituted C1 to C5 alkyl group, a substituted or unsubstituted C2 to C5 alkenyl group, a substituted or unsubstituted C2 to C5 alkynyl group, a hydrophilic group, or any combination thereof, and
at least two of R³ to R⁶ are hydrophilic groups,
L¹ to L⁴ are each independently a single bond or a substituted or unsubstituted C1 to C10 alkylene group that does not include fluorine,
L⁵ to L⁸ are each independently a single bond; a substituted or unsubstituted C1 to C10 alkylene group that does not include fluorine; a substituted or unsubstituted C2 to C10 alkenylene group that does not include fluorine; a substituted or unsubstituted C2 to C10 alkynylene group that does not include fluorine; a substituted or unsubstituted C6 to C12 arylene group that does not include fluorine, or any combination thereof, and
n1 is an integer from 0 to 5. As referred to herein, a group that does not include fluorine may also be referred to as devoid of fluorine or free from fluorine.

In an example embodiment, X¹ may be a nonionic hydrophilic group, and at least one of R³ to R⁶ may be an anionic hydrophilic group, and at least one of the others may be a nonionic hydrophilic group, an anionic hydrophilic group, a cationic hydrophilic group, or any combination thereof.

In some embodiments, X¹ may be a nonionic hydrophilic group, at least one of R³ to R⁶ may be an anionic hydrophilic group, and at least one of the others may be a nonionic hydrophilic group, an anionic hydrophilic group, or any combination thereof.

For example, X¹ may include a nonionic hydrophilic group selected from an amide group (—NHC(═O)—), a thioamide group (—NHC(═S)—), an ester group (—OC(═O)—), and a sulfone group (—S(═O)₂).

In an embodiment, X¹ may be an amide group (—NHC(═O)—).

Meanwhile, the compound represented by Chemical Formula 1 may be a per- and polyfluoroalkyl substance-free compound (e.g., devoid of, or free from, fluorine substitutions on alkyl, alkenyl and/or alkynyl groups), and in the definition of Chemical Formula 1, the “substituted” means substitution with a C1 to C5 alkyl group, a C2 to C5 alkenyl group, a C2 to C5 alkynyl group, or any combination thereof. In some embodiments, one or more of Y¹ to Y⁴, R¹ to R⁶, and L¹ to L⁸ are substituted, with each substitution independently selected from a C1 to C5 alkyl group, a C2 to C5 alkenyl group, a C2 to C5 alkynyl group, or any combination thereof.

For example, at least one of R³ to R⁶ may include an anionic hydrophilic group selected from a sulfonic acid salt (—SO₃⁻), a sulfonic acid (—SO₃H), a carboxylic acid salt (—CO₂⁻), a carboxylic acid (—CO₂H), a dicarboxylic acid salt (—OC(O)(CH₂)ₙ₂C(O)O⁻), dicarboxylic acid (—OC(O)(CH₂)ₙ₂C(O)OH), phosphate (—HPO₃⁻), and phosphoric acid (—H₂PO₄), wherein n2 is an integer from 1 to 5, and
at least one of the other R³ to R⁶ may include a nonionic hydrophilic group selected from a hydroxy group, an amide group (—NHC(═O)—), a thioamide group (—NHC(═S)—), an ester group (—OC(═O)—), and a sulfone group (—S(═O)₂), or an anionic hydrophilic group selected from a sulfonic acid salt (—SO₃—), sulfonic acid (—SO₃H), a carboxylic acid salt (—CO₂—), carboxylic acid (—CO₂H), dicarboxylic acid salt (—OC(O)(CH₂)ₙ₂C(O)O⁻), dicarboxylic acid (—OC(O)(CH₂)ₙ₂C(O)OH), phosphate (—HPO₃⁻), and phosphoric acid (—H₂PO₄), wherein n2 is an integer from 1 to 5.

In an embodiment, at least one of R³ to R⁶ may include an anionic hydrophilic group selected from a sulfonic acid salt (—SO₃⁻), sulfonic acid (—SO₃H), a carboxylic acid salt (—CO₂⁻), carboxylic acid (—CO₂H), a dicarboxylic acid salt (—OC(O)(CH₂)ₙ₂C(O)O⁻), dicarboxylic acid (—OC(O)(CH₂)ₙ₂C(O)OH), phosphate (—HPO₃⁻), and phosphoric acid (—H₂PO₄), wherein n2 is an integer from 1 to 5, and
at least one of the other R³ to R⁶ may include a nonionic hydrophilic group selected from a hydroxy group, an amide group (—NHC(═O)—), an ester group (—OC(═O)—), and a sulfone group (—S(═O)₂); or an anionic hydrophilic group selected from a sulfonic acid salt (—SO₃—), sulfonic acid (—SO₃H), a carboxylic acid salt (—CO₂—), carboxylic acid (—CO₂H), dicarboxylic acid salt (—OC(O)(CH₂)ₙ₂C(O)O⁻), dicarboxylic acid (—OC(O)(CH₂)ₙ₂C(O)OH), phosphate (—HPO₃⁻), and phosphoric acid (—H₂PO₄), wherein n2 is an integer from 1 to 5.

In another embodiment, at least one of L³ and L⁴ may further include one or more hydrophilic groups.

The additionally included hydrophilic group (e.g., at least one of L³ and L⁴) may be, for example, a nonionic hydrophilic group, and specifically, a nonionic hydrophilic group selected from an amide group (—NHC(═O)—), a thioamide group (—NHC(═S)—), an ester group (—OC(═O)—), and a sulfone group (—S(═O)₂).

Specifically, n1 may be one of the integers from 0 to 4, one of the integers from 0 to 3, or one of the integers from 0 to 2.

In an embodiment, L⁵ to L⁸ may each independently be a single bond; a substituted or unsubstituted C1 to C10 alkylene group that does not include fluorine; or a substituted or unsubstituted C6 to C12 arylene group that does not include fluorine.

In a specific embodiment, L⁵ to L⁸ may each independently be a single bond; a substituted or unsubstituted C1 to C2 alkylene group that does not include fluorine; or a substituted or unsubstituted C6 to C10 arylene group that does not include fluorine.

For example, L⁵ to L⁸ may each independently be a single bond; a substituted or unsubstituted methylene group that does not include fluorine; a substituted or unsubstituted ethylene group that does not include fluorine; or a substituted or unsubstituted phenylene group that does not include fluorine.

In an embodiment of the present disclosure, the surfactant may be included at a concentration of about 10 to about 10,000 ppm, about 50 to about 10,000 ppm, and for example about 50 to about 3,000 ppm, based on a total amount of the rinse composition. When the surfactant concentration is within the above range, the effect of improving the pattern collapse phenomenon (e.g., reducing pattern collapse) may be more effective.

The solvent may be water, for example, deionized water. When using deionized water, process costs are reduced and handling and wastewater treatment are easy.

The solvent may be included in a balance amount excluding other components.

The photolithographic rinse composition according to an embodiment of the present disclosure may further include at least one additional additive selected from an acid additive and a hydrophilic organic solvent.

The acid additive may remove impurities remaining on the surface of the semiconductor substrate and further improve the line width roughness (LWR) of the pattern.

The acid additive may include an organic acid, an inorganic acid, or a mixture thereof.

The organic acid may include an aliphatic organic acid and/or an aromatic organic acid. The aliphatic organic acid may include formic acid, acetic acid, propionic acid, butyric acid, palmitic acid, stearic acid, oleic acid, oxalic acid, malonic acid, succinic acid, tartaric acid, maleic acid, glycolic acid, glutaric acid, adipic acid, sulfosuccinic acid, valeric acid, caproic acid, caprylic acid, capric acid, loric acid, myristic acid, lactic acid, malic acid, citric acid, and tartaric acid. The aromatic organic acid may include benzoic acid, salicylic acid, p-toluenesulfonic acid, naphthoic acid, nicotinic acid, toluic acid, anisic acid, cuminic acid, and phthalic acid. These can be used alone or in combination of two or more types.

The inorganic acid may be one or more selected from carbonic acid, phosphoric acid, nitric acid, sulfuric acid, and/or hydrochloric acid.

A content of the acid additive may be adjusted according to a pH value indicating acidity within a range that does not damage the photoresist pattern.

For example, the acid additive may be included at a concentration of about 1 to about 10,000 ppm, about 5 to about 10,000 ppm, about 10 to about 5,000 ppm, and for example about 10 to about 1,000 ppm, based on a total amount of the rinse composition.

The hydrophilic organic solvent may improve pattern collapse or improve LWR by lowering the surface tension of the rinse composition.

The hydrophilic organic solvent may include at least one selected from alcohols, pyridines, cyclic ethers, glycol ethers, glycol ether acetates, hydrocarbons, ketones, lactones, and/or esters.

A content of the organic solvent may be appropriately adjusted within a range that does not damage the photoresist pattern.

For example, the hydrophilic organic solvent may be included in an amount of about 0 to about 20 wt %, and for example about 0 to about 10 wt %, based on a total 100 wt % of the solvent.

The additional additive may be a unimolecular compound with a number average molecular weight of less than or equal to about 1,000.

The rinse composition according to the present disclosure can be suitably used in the rinsing process after developing a photoresist pattern. Specifically, it can be used after spraying the developer and spraying water for cleaning thereof, and before the spin drying process.

The rinse composition may be removed in the spin drying process.

In some cases, the order of spraying the developer, spraying water for cleaning, and spraying the rinse composition may be changed flexibly, and water spraying may be additionally performed after spraying the rinse composition.

The surfactant may be selected from compounds listed in Group 1.

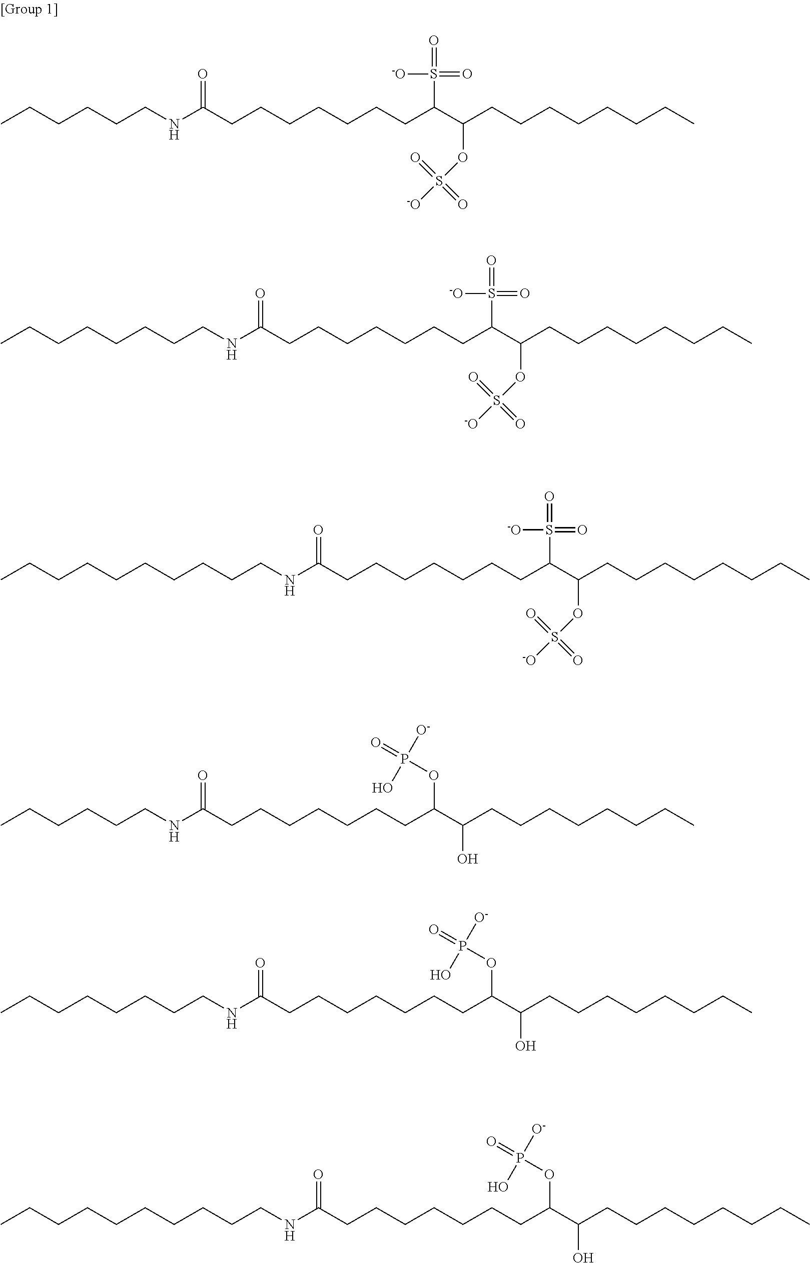

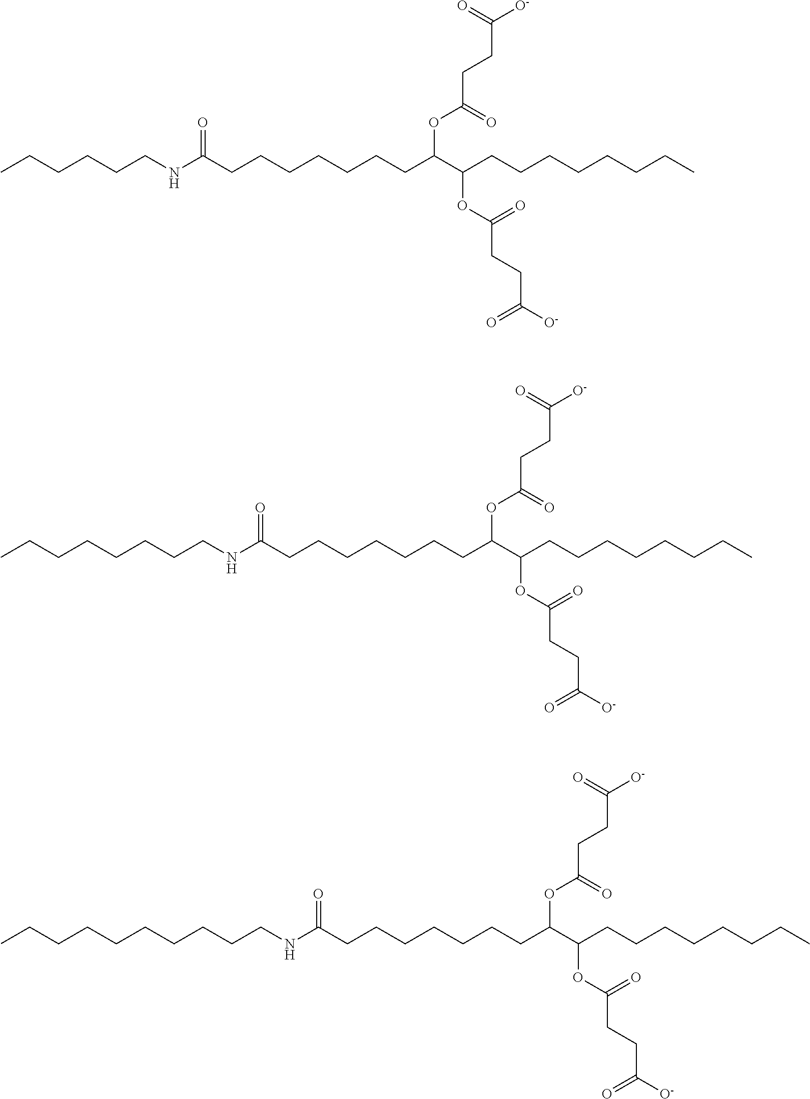

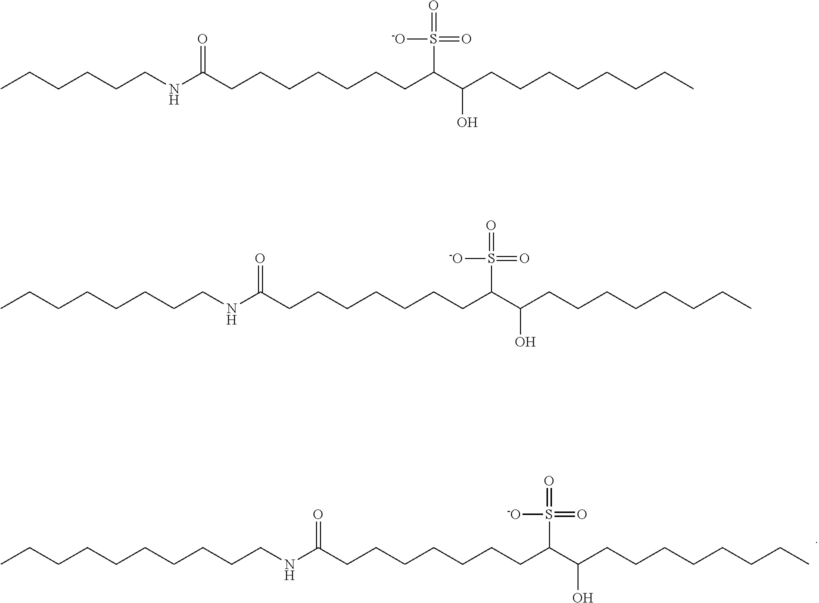

Using the photolithographic rinse composition, pattern collapse may not occur even if a pattern with a high aspect ratio is formed. Therefore, for example, in order to form a micropattern with a width of about 5 nm to about 100 nm, for example, a micropattern with a width of about 5 nm to about 80 nm, for example, a micropattern with a width of about 5 nm to about 70 nm, for example, a micropattern with a width of about 5 nm to about 50 nm, for example, a micropattern with a width of about 5 nm to about 40 nm, for example, a micropattern with a width of about 5 nm to about 30 nm, for example, a micropattern with a width of about 5 nm to about 20 nm, for example, a micropattern with a width of about 5 nm to about 10 nm, a photoresist process using light with a wavelength of about 5 nm to about 150 nm, for example a photoresist process using light with a wavelength of about 5 nm to about 100 nm, for example, a photoresist process using light with a wavelength of about 5 nm to about 80 nm, for example, a photoresist process using light with a wavelength of about 5 nm to about 50 nm, for example, a photoresist process using light with a wavelength of about 5 nm to about 30 nm, for example, a photoresist process using light with a wavelength of about 5 nm to about 20 nm may be used. Therefore, by using the semiconductor photoresist composition according to an embodiment, extreme ultraviolet lithography using an EUV light source with a wavelength of about 13.5 nm may be implemented.

In particular, the photoresist pattern can effectively prevent pattern collapse even for patterns having a pattern spacing of about 15 nm to about 40 nm.

Meanwhile, according to another embodiment, a method of forming patterns using the aforementioned rinse composition may be provided. As an example, the manufactured pattern may be a photoresist pattern.

A method of forming patterns according to another embodiment includes forming a photoresist film on a substrate, exposing the photoresist film, patterning the exposed photoresist film to form a photoresist pattern, and washing the photoresist pattern using the aforementioned rinse composition.

In the step of washing the photoresist pattern, the surfactant is distributed at the interface of the photoresist pattern-solvent and solvent-air, and a surface distribution ratio (m1/m2) calculated as the number of surfactant molecules (m1) distributed at the interface of the photoresist pattern-solvent relative to the number of molecules (m2) of the surfactant distributed at the solvent-air interface may be greater than about 1.3.

Specifically, the surface distribution ratio (m1/m2) may be about 1.3 to about 2, for example, about 1.3 to about 1.8.

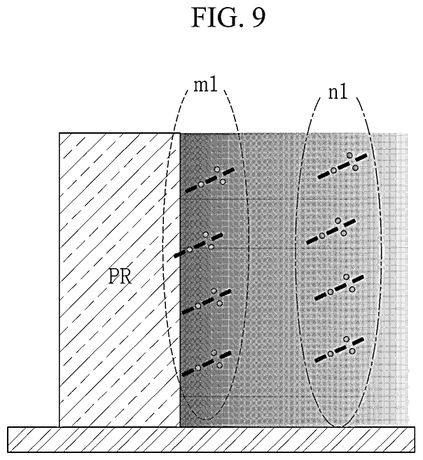

The surface distribution ratio may be explained in the schematic view shown in FIG. 9.

FIG. 9 is a schematic view for explaining a method of calculating the surface distribution ratio from the number of molecules distributed for each of the photoresist pattern-solvent interface and the solvent-air interface.

Referring to FIG. 9, when the number of surfactant molecules distributed at the interface of the photoresist pattern-solvent is m1 and the number of surfactant molecules distributed at the solvent-air interface is m2, the surface distribution ratio (K) may be calculated as m1/m2.

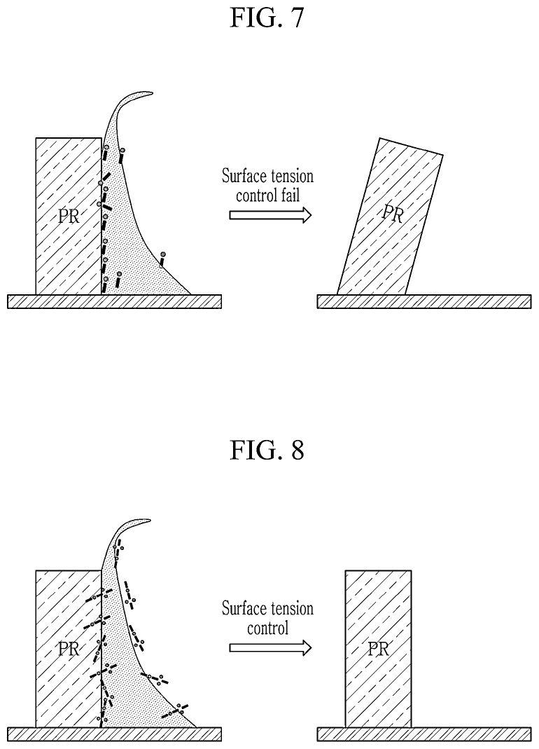

FIGS. 7 and 8 are schematic views showing degrees of distribution according to the structures of surfactants to calculate the surface distribution ratios (K).

Referring to FIG. 7, when a surfactant in which hydrophilic functional groups and hydrophobic functional groups are connected only in series is distributed on the surface, the surfactant is not evenly distributed between the photoresist pattern-solvent interface and the solvent-air interface, and an imbalance may occur that is mainly distributed only at the photoresist pattern-solvent interface, so that surface tension may not be controlled during the spin drying process and pattern collapse may occur.

On the other hand, referring to FIG. 8, when the surfactant according to the present disclosure, that is, a surfactant in which two or more hydrophilic groups and two or more hydrophobic groups are connected in a series/parallel mixed structure, is distributed on the surface, the pattern collapse may not occur even after spin drying because the surfactant can be evenly distributed between the photoresist pattern-solvent interface and the solvent-air interface.

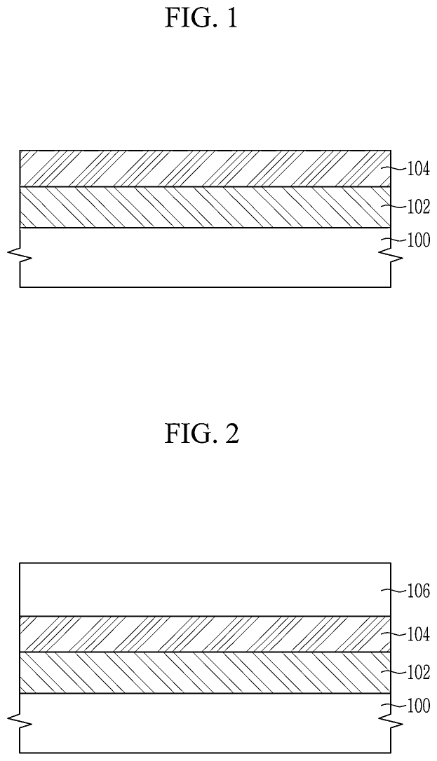

Hereinafter, a method of forming patterns will be exemplarily described with reference to FIGS. 1 to 5.

Referring to FIG. 1, first, an object to be etched is prepared. An example of the object to be etched may be the thin film 102 formed on the semiconductor substrate 100. Hereinafter, only the case where the object to be etched is the thin film 102 will be described. The surface of the thin film 102 is cleaned to remove contaminants remaining on the thin film 102. The thin film 102 may be, for example, a silicon nitride film, a polysilicon film, or a silicon oxide film.

Next, a composition for forming a resist underlayer to provide a resist underlayer 104 is coated on the surface of the cleaned thin film 102 by applying a spin coating method. However, embodiments are not necessarily limited to the above, and various known coating methods such as spray coating, dip coating, knife edge coating, and printing methods such as inkjet printing and screen printing may be used.

In some embodiments, the resist underlayer coating process may be omitted. In some embodiments, an exemplary approach of coating the resist underlayer will be described below.

Afterwards, a drying and baking process is performed to form a resist underlayer 104 on the thin film 102. The baking treatment may be performed at about 100 to about 500° C., for example, about 100° C. to about 300° C.

The resist underlayer 104 is formed between the substrate 100 and the photoresist film 106, so that when radiation reflected from the interface between the substrate 100 and the photoresist film 106 or the interlayer hardmask is scattered into an unintended photoresist region, non-uniformity of the photoresist linewidth and interference with pattern-forming capability may be prevented.

Referring to FIG. 2, a semiconductor photoresist composition is coated on the resist underlayer 104 to form a photoresist film 106. The photoresist film 106 may be formed by coating a semiconductor photoresist composition on the thin film 102 on the substrate 100 and then curing it through a heat treatment process.

More specifically, the forming of a pattern using a semiconductor photoresist composition may include coating the aforementioned semiconductor resist composition on the substrate 100 on which the thin film 102 is formed by spin coating, slit coating, inkjet printing, etc., and drying the coated semiconductor photoresist composition to form a photoresist film 106.

Next, a first baking process is performed to heat the substrate 100 on which the photoresist film 106 is formed. The first baking process may be performed at a temperature of about 80° C. to about 120° C.

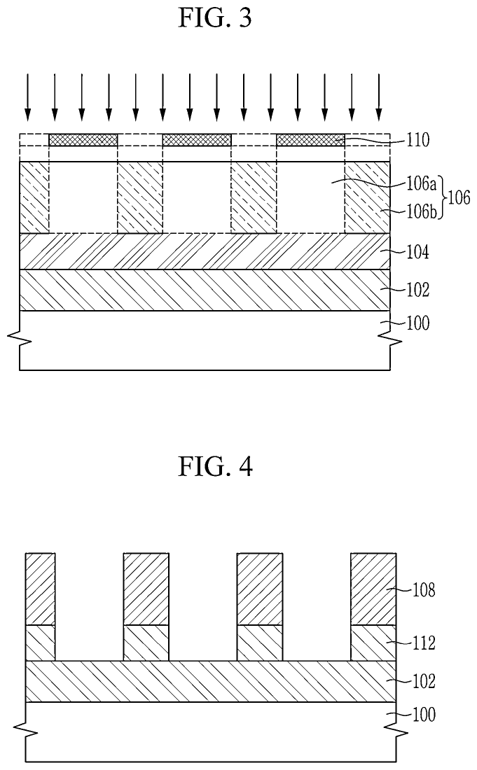

Referring to FIG. 3, the photoresist film 106 is selectively exposed using a patterned mask 110.

For example, examples of light that can be used in the exposure process may include light with a short wavelength such as activating radiation i-line (wavelength 365 nm), KrF excimer laser (wavelength of about 248 nm), and ArF excimer laser (wavelength of about 193 nm), as well as light with high energy wavelengths such as EUV (Extreme UltraViolet; wavelength of about 13.5 nm) and E-Beam (electron beam).

More specifically, the exposure light according to an embodiment may be short-wavelength light having a wavelength range of about 5 nm to about 150 nm, and may be light having a high-energy wavelength such as EUV (Extreme UltraViolet; wavelength of about 13.5 nm) or E-Beam (electron beam).

The exposed region 106b of the photoresist film 106 has a different solubility from the unexposed region 106a of the photoresist film 106 as a polymer is formed through a crosslinking reaction such as condensation between organometallic compounds.

Next, a second baking process is performed on the substrate 100. The second baking process may be performed at a temperature of about 90° C. to about 200° C. By performing the second baking process, the exposed region 106b of the photoresist film 106 becomes difficult to dissolve in the developer.

FIG. 4 shows a photoresist pattern 108 formed by dissolving and removing the photoresist film 106a corresponding to the unexposed region using a developer to pattern the photoresist film 106a. Specifically, the photoresist film 106a corresponding to the unexposed region is dissolved and then removed using an organic solvent such as 2-heptanone, thereby forming a photoresist pattern 108 corresponding to the negative tone image.

The developer used in the method of forming patterns according to an embodiment may be an organic solvent. Examples of organic solvents used in the method of forming patterns according to an embodiment may include ketones such as methylethylketone, acetone, cyclohexanone, 2-heptanone, and the like, alcohols such as 4-methyl-2-propanol, 1-butanol, isopropanol, 1-propanol, methanol, and the like, esters such as propylene glycol monomethyl ether acetate, ethyl acetate, ethyl lactate, n-butyl acetate, butyrolactone, and the like, aromatic compounds such as benzene, xylene, toluene, and the like, or any combination thereof.

However, the photoresist pattern according to some embodiments is not necessarily limited to the negative tone image but may be formed to have a positive tone image. Herein, a developer used for forming the positive tone image may be a quaternary ammonium hydroxide composition such as tetraethylammonium hydroxide, tetrapropylammonium hydroxide, tetrabutylammonium hydroxide, or any combination thereof.

As described above, exposure to light having a high energy such as EUV (extreme ultraViolet; a wavelength of 13.5 nm), an E-Beam (an electron beam), and the like as well as light having a wavelength such as i-line (wavelength of about 365 nm), KrF excimer laser (wavelength of about 248 nm), ArF excimer laser (wavelength of about 193 nm), and the like may provide a photoresist pattern 108 having a width of a thickness of about 5 nm to about 100 nm. For example, the photoresist pattern 108 may be formed to have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

On the other hand, the photoresist pattern 108 may have a pitch of having a half-pitch of less than or equal to about 50 nm, for example less than or equal to about 40 nm, for example less than or equal to about 30 nm, for example less than or equal to about 20 nm, or for example less than or equal to about 10 nm, and for example greater than or equal to about 5 nm, for example greater than or equal to about 10 nm, or for example greater than or equal to about 15 nm, and for example about 15 nm to about 40 nm and a line width roughness of less than or equal to about 5 nm, less than or equal to about 3 nm, less than or equal to about 2 nm, or less than or equal to about 1 nm.

Next, the resist underlayer 104 is etched using the photoresist pattern 108 as an etch mask. Through this etching process, an organic layer pattern 112 is formed. The organic layer pattern 112 also may have a width corresponding to that of the photoresist pattern 108.

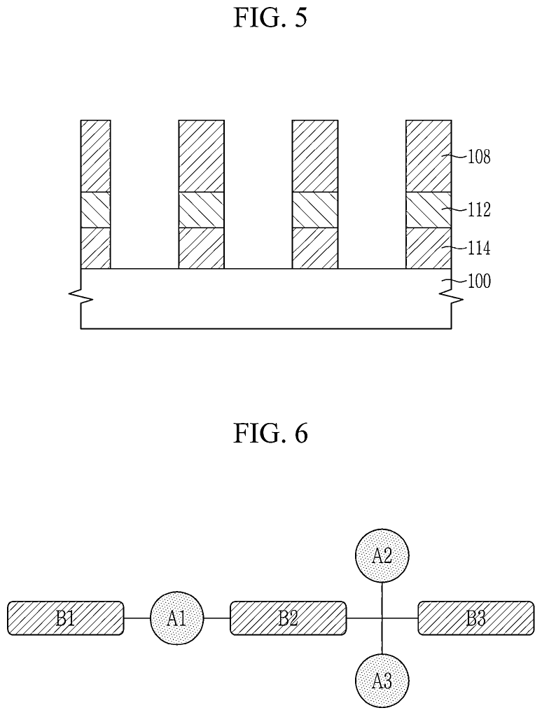

Referring to FIG. 5, the exposed thin film 102 is etched by applying the photoresist pattern 108 as an etching mask. As a result, the thin film is formed as a thin film pattern 114.

The etching of the thin film 102 may be for example dry etching using an etching gas and the etching gas may be for example CHF₃, CF₄, Cl₂, BCl₃ and a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of 5 nm to 100 nm which is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and more specifically a width of less than or equal to about 20 nm, like that of the photoresist pattern 108.

Hereinafter, the present disclosure will be described in more detail through examples related to the preparation of the aforementioned photolithographic rinse composition. However, the technical features of the present disclosure are not limited to the following examples.

### Preparation of Rinse Compositions

### Examples 1 to 11 and Comparative Examples 1 to 3

As shown in Table 1, a rinse composition was prepared by mixing each component.

TABLE 1

| | Surfactant (ppm) | | | | |
|---|---|---|---|---|---|
| | (A-1) | (A-2) | (A-3) | (B) | Water |
| Example 1 | 500 | — | — | — | Balance amount |
| Example 2 | — | 300 | — | — | Balance amount |
| Example 3 | — | — | 300 | — | Balance amount |
| Comparative Example 1 | — | — | — | 100 | Balance amount |

(A-1) Compound represented by Chemical Formula 1a 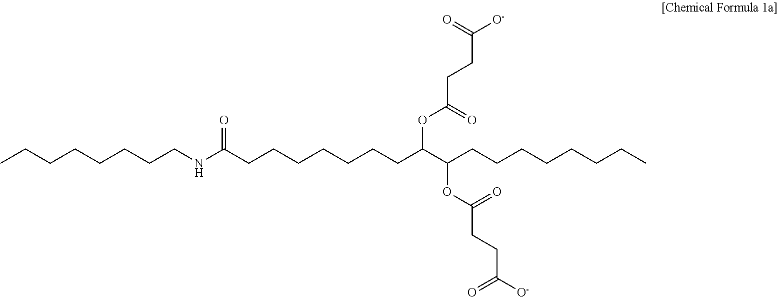 [SMILES: CCCCCCCCNC(=O)CCCCCCCC(OC(=O)CCC(=O)[O-])C(CCCCCCCC)OC(=O)CCC(=O)[O-]]
(A-2) Compound represented by Chemical Formula 2a 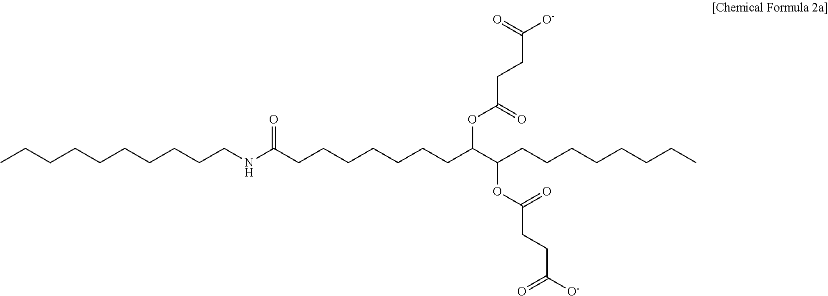 [SMILES: CCCCCCCCCCNC(=O)CCCCCCCC(OC(=O)CCC(=O)[O-])C(CCCCCCCC)OC(=O)CCC(=O)[O-]]
(A-3) Compound represented by Chemical Formula 3a 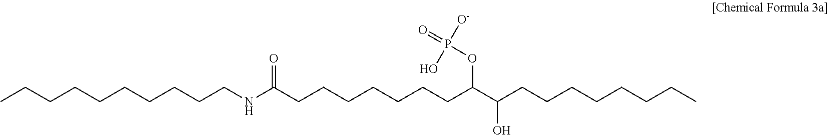 [SMILES: CCCCCCCCCCNC(=O)CCCCCCCC(OP(=O)([O-])O)C(O)CCCCCCCC]
(B) Compound represented by Chemical Formula b

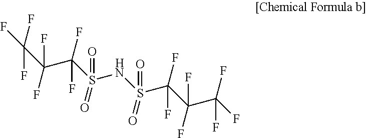 [SMILES: O=S(=O)(NS(=O)(=O)C(F)(F)C(F)(F)C(F)(F)F)C(F)(F)C(F)(F)C(F)(F)F]

### (1) Evaluation of Surface Tension

Each of the rinse compositions according to the examples and the comparative examples was measured with respect to surface tension at 25° C. by using a surface tensiometer K100 (KRÜSS), and the results are shown in Table 2.

### (2) Evaluation of DOF (Depth of Focus) Margin

A silicon wafer (SUMCO, 12 inch) was surface-treated with 1,1,1,3,3,3-hexamethyl disilazane (HMDS) at 90° C. for 60 seconds. Subsequently, a chemically-amplified PHS acrylate hydrate hybrid EUV resist was spin-coated on the silicon wafer and then soft-baked at 110° C. for 60 seconds to form a 50 nm-thick resist film. The resist film on the wafer was exposed through a mask with a size of 20 nm (line:space=1:1) by changing an exposure dose in an EUV exposure apparatus (High NA Small Field Exposure Tool, NA=0.51, quadrupole). After exposing the wafer at 110° C. for 60 seconds, the wafer was baked (PEB). Then, the resist film was puddle-developed in a 2.38% tetramethylammonium hydroxide (TMAH) aqueous solution for 30 seconds. After pouring rinse water into a puddle of a developer on the wafer and then, rotating the wafer to change the developer to the rinse water, while continuously pouring water, the rotation was stopped by the water in a puddled state. Subsequently, each of the surfactants according to Examples 1 to 3 and Comparative Example 1 was introduced into the puddle of the water (deionized water), and the wafer was rotated at a high speed to dry the water. Then, the wafer was hard-baked at 100° C. for 60 seconds.

TABLE 2

| | Surface | Surface | DOF |
|---|---|---|---|
| | distribution ratio | tension | margin |
| | (K) | (mN/m) | (nm) |
| Example 1 | 1.5 | 45 | 80 |
| Example 2 | 1.4 | 42 | 70 |
| Example 3 | 1.4 | 38 | 65 |
| Comparative Example 1 | 1.3 | 46 | 60 |

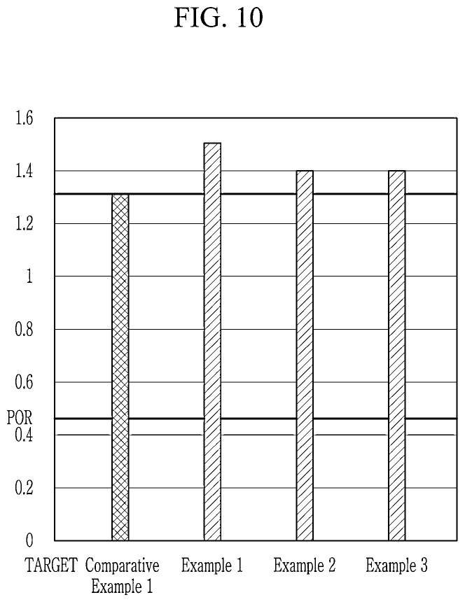

The surface distribution ratio (K) was calculated through MD simulation, and the results are shown in FIG. 10.

FIG. 10 shows the surface distribution ratios (K) according to Comparative Example 1 and Examples 1 to 3.

Referring to FIG. 10, when a surfactant with a hydrophilic functional group and a hydrophobic functional group linked only in series (Comparative Example 1) was distributed on the surface, the surface distribution ratio (K) was about 1.3, but when a surfactant with two or more hydrophilic groups and two or more hydrophobic groups linked in a series/parallel mixed structure was distributed on the surface (Examples 1 to 3), the surface distribution ratio (K) was about 1.4 or about 1.5, which was greater than 1.3.

In this regard, referring to Table 2, when the surface distribution ratio (K) was about 1.3, a focus margin of about 60 nm was secured in a line-space pattern of 40 pitch or less, but when the surface distribution ratio (K) was greater than 1.3, the focus margin was improved to 80 nm.

While the present invention has been particularly shown and described with reference to exemplary embodiments thereof, it is to be understood that the invention is not limited to the disclosed exemplary embodiments, but, on the contrary, is intended to cover various modifications and equivalent arrangements included within the spirit and scope of the appended claims.

<Description of Symbols>

| | |
|---|---|
| 100: substrate | 102: thin film |
| 104: resist underlayer | 106: photoresist film |
| 106a: unexposed region | 106b: exposed region |
| 108: photoresist pattern | 112: organic layer pattern |
| 110: patterned mask | 114: thin film pattern |
| A1, A2, A3: hydrophilic group | |
| B1, B2, B3: hydrophobic group | |

What is claimed is:

1. A photolithographic rinse composition, comprising
a gemini-type surfactant having a main chain including at least two hydrophobic groups, at least one hydrophilic group, at least two side chains branching from the main chain, and a hydrophilic group-including functional group; and
a solvent.

2. The photolithographic rinse composition of claim 1, wherein
the surfactant includes a compound represented by Chemical Formula 1: 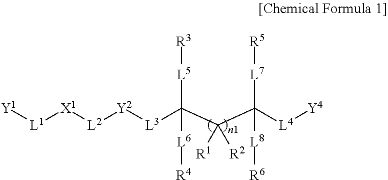
wherein, in Chemical Formula 1,
Y¹ and Y⁴ are each independently a substituted or unsubstituted C2 to C12 alkyl group that does not include fluorine; a substituted or unsubstituted C2 to C12 alkenyl group that does not include fluorine; a substituted or unsubstituted C2 to C12 alkynyl group that does not include fluorine, or any combination thereof,
Y² is a substituted or unsubstituted C1 to C10 alkylene group that does not include fluorine; a substituted or unsubstituted C2 to C10 alkenylene group that does not include fluorine; a substituted or unsubstituted C2 to C10 alkynylene group that does not include fluorine, or any combination thereof,
X¹ is a hydrophilic group,
R¹ and R² are each independently a hydrogen atom, a substituted or unsubstituted C1 to C5 alkyl group that does not include fluorine, a substituted or unsubstituted C2 to C5 alkenyl group that does not include fluorine, a substituted or unsubstituted C2 to C5 alkynyl group that does not include fluorine, or any combination thereof;
R³ to R⁶ are each independently a hydrogen atom, a substituted or unsubstituted C1 to C5 alkyl group, a substituted or unsubstituted C2 to C5 alkenyl group, a substituted or unsubstituted C2 to C5 alkynyl group, a hydrophilic group, or any combination thereof, wherein at least two of R³ to R⁶ are hydrophilic groups;
L¹ to L⁴ are each independently a single bond, a substituted or unsubstituted C1 to C10 alkylene group that does not include fluorine, a substituted or unsubstituted C2 to C10 alkenylene group that does not include fluorine, a substituted or unsubstituted C2 to C10 alkynylene group that does not include fluorine, or any combination thereof;
L⁵ to L⁸ are each independently a single bond, a substituted or unsubstituted C1 to C10 alkylene group that does not include fluorine, a substituted or unsubstituted C2 to C10 alkenylene group that does not include fluorine, a substituted or unsubstituted C2 to C10 alkynylene group that does not include fluorine, a substituted or unsubstituted C6 to C12 arylene group that does not include fluorine, or any combination thereof; and
n1 is an integer from 0 to 5.

3. The photolithographic rinse composition of claim 2, wherein
X¹ is a nonionic hydrophilic group; and
at least one of R³ to R⁶ is a nonionic hydrophilic group, and at least one of the other R³ to R⁶ is a nonionic hydrophilic group, an anionic hydrophilic group, a cationic hydrophilic group, or any combination thereof.

4. The photolithographic rinse composition of claim 2, wherein
X¹ is a nonionic hydrophilic group selected from an amide group (—NHC(═O)—), a thioamide group (—NHC(═S)—), an ester group (—OC(═O)—), and a sulfone group (—S(═O)₂).

5. The photolithographic rinse composition of claim 2, wherein
wherein when one or more of Y¹ to Y⁴, R¹ to R⁶, and L¹ to L⁸ are substituted, each substitution is independently selected from a C1 to C5 alkyl group, a C2 to C5 alkenyl group, a C2 to C5 alkynyl group, or any combination thereof.

6. The photolithographic rinse composition of claim 2, wherein
at least one of R³ to R⁶ includes an anionic hydrophilic group selected from a sulfonic acid salt (—SO₃—), sulfonic acid (—SO₃H), a carboxylic acid salt (—CO₂—), carboxylic acid (—CO₂H), dicarboxylic acid salt (—OC(O)(CH₂)ₙ₂C(O)O⁻), dicarboxylic acid (—OC(O)(CH₂)ₙ₂C(O)OH), phosphate (—HPO₃⁻), and phosphoric acid (—H₂PO₄), wherein n2 is an integer from 1 to 5, and
at least one of the other R³ to R⁶ includes a nonionic hydrophilic group selected from a hydroxy group, an amide group (—NHC(═O)—), a thioamide group (—NHC(═S)—), an ester group (—OC(═O)—), and a sulfone group (—S(═O)₂), or an anionic hydrophilic group selected from a sulfonic acid salt (—SO₃—), sulfonic acid (—SO₃H), a carboxylic acid salt (—CO₂−), carboxylic acid (—CO₂H), dicarboxylic acid salt (—OC(O)(CH₂)ₙ₂C(O)O⁻), dicarboxylic acid (—OC(O)(CH₂)ₙ₂C(O)OH), phosphate (—HPO₃⁻), and phosphoric acid (—H₂PO₄), wherein n2 is an integer from 1 to 5.

7. The photolithographic rinse composition of claim 2, wherein at least one of L³ and L⁴ further includes one or more hydrophilic groups.

8. The photolithographic rinse composition of claim 7, wherein the hydrophilic group is a nonionic hydrophilic group.

9. The photolithographic rinse composition of claim 2, wherein n1 is one of the integers from 0 to 2.

10. The photolithographic rinse composition of claim 2, wherein
L⁵ to L⁸ are each independently a single bond; a substituted or unsubstituted C1 to C2 alkylene group that does not include fluorine; or a substituted or unsubstituted C6 to C10 arylene group that does not include fluorine.

11. The photolithographic rinse composition of claim 1, wherein
the surfactant is included at a concentration of about 10 to about 10,000 ppm based on a total amount of the rinse composition.

12. The photolithographic rinse composition of claim 1, wherein
at least one additional additive selected from an acid additive and a hydrophilic organic solvent is further included.

13. The photolithographic rinse composition of claim 12, wherein
the acid additive is included at a concentration of about 1 to about 10,000 ppm based on a total amount of the rinse composition.

14. The photolithographic rinse composition of claim 12, wherein
the hydrophilic organic solvent is included in an amount of about 0 to about 20 wt % based on a total 100 wt % of the solvent.

15. The photolithographic rinse composition of claim 12, wherein the additional additive is a unimolecular compound with a number average molecular weight of less than or equal to about 1,000.

16. The photolithographic rinse composition of claim 1, wherein
the surfactant is selected from compounds listed in Group 1:

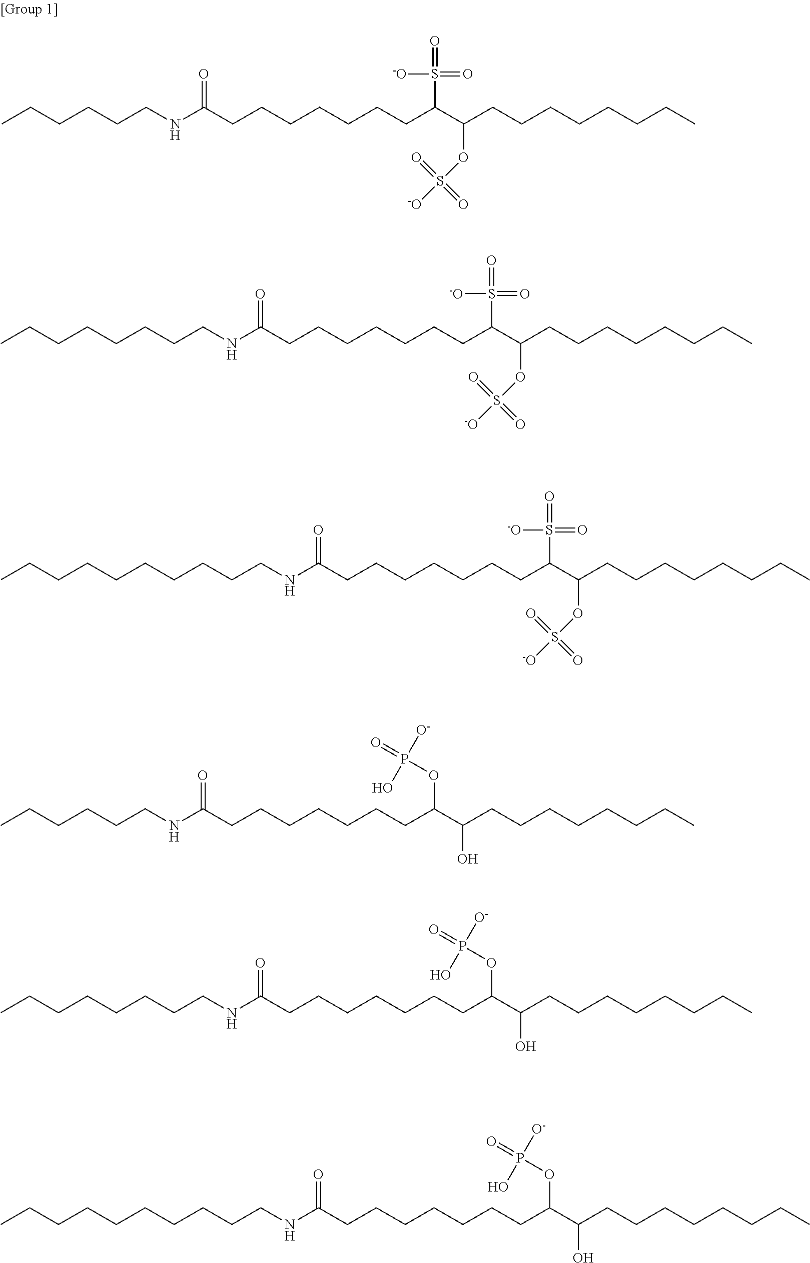

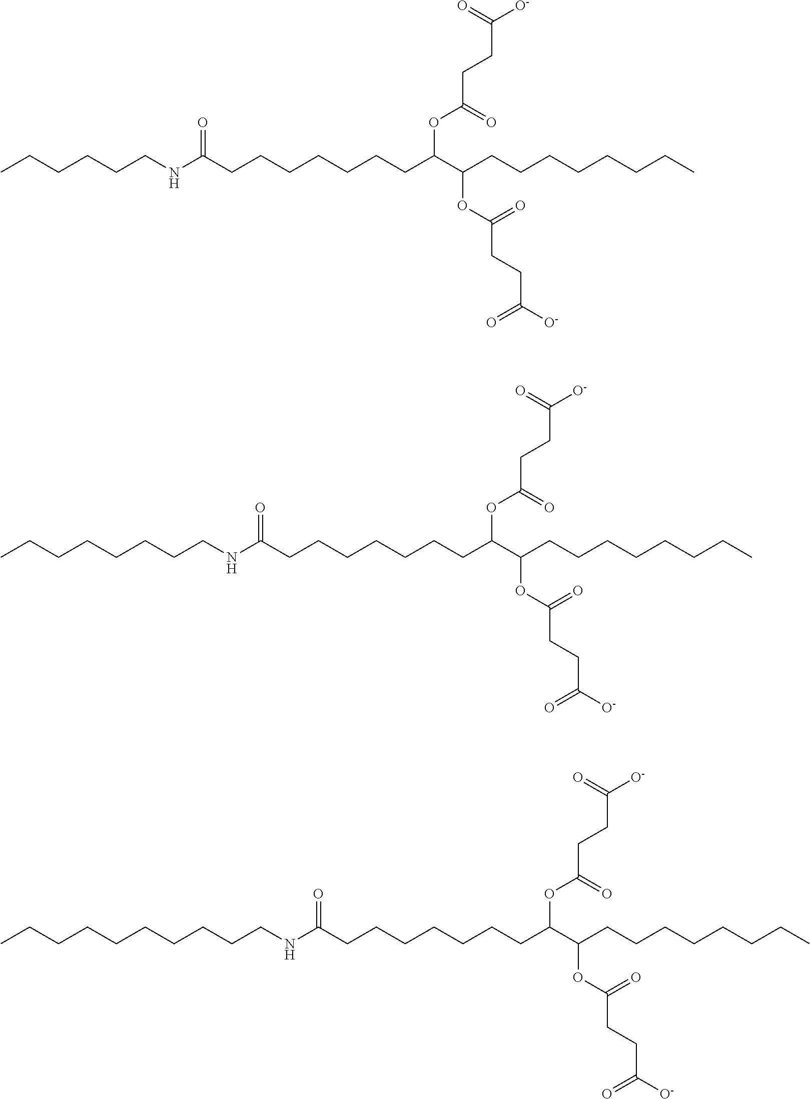

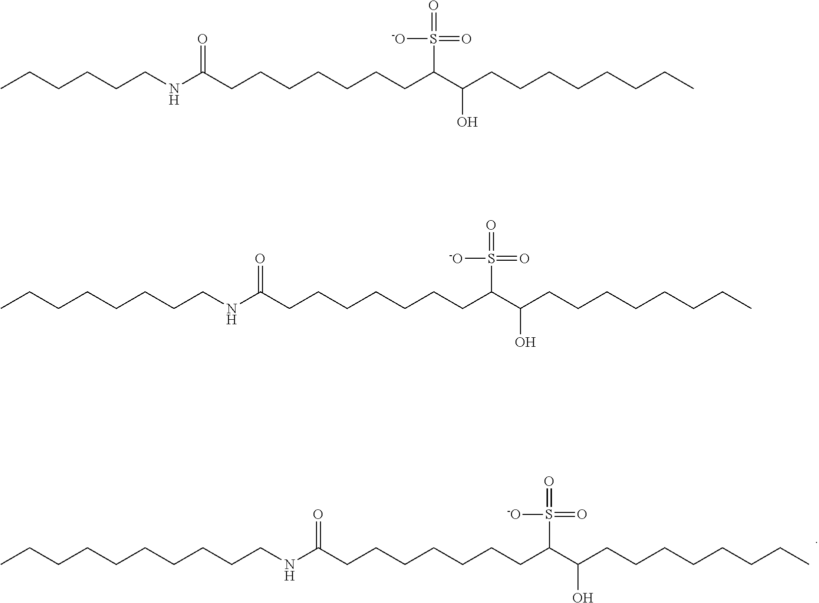

17. A method of forming patterns, comprising
forming a photoresist film on a substrate;
exposing a photoresist film;
patterning the exposed photoresist film to form a photoresist pattern; and
washing the photoresist pattern using the rinse composition of claim 1.

18. The method of claim 17, wherein
in the washing of the photoresist pattern,
the surfactant is distributed at the interface of the photoresist pattern-solvent and solvent-air, and
a surface distribution ratio (m1/m2) calculated as the number of surfactant molecules (m1) distributed at the interface of the photoresist pattern-solvent relative to the number of molecules (m2) of the surfactant distributed at the solvent-air interface is greater than about 1.3.

19. The method of claim 17, wherein
in the forming of the photoresist pattern, light having a wavelength range of about 5 nm to about 150 nm is used.

20. The method of claim 17, wherein
the photoresist pattern has a pattern spacing of about 15 nm to about 40 nm.
